(19) United States
(12) Patent Application Publication
(10) Pub. No.: US 2026/0372085 A1
(43) Pub. Date: Nov. 19, 2026

(54) On-Board Electronic Control Device

(71) Applicant: Astemo, Ltd., Chiyoda-ku, Tokyo (JP)

(72) Inventors: Yasuhiro TSUYUKI, Tokyo (JP); Yoshio KAWAI, Hitachinaka-shi, Ibaraki (JP); Keiko UENO, Hitachinaka-shi, Ibaraki (JP); Ryo AKIBA, Hitachinaka-shi, Ibaraki (JP); Akihiro NAMBA, Tokyo (JP)

(21) Appl. No.: 19/133,784

(22) PCT Filed: Aug. 28, 2023
(86) PCT No.: PCT/JP2023/030998

§ 371 Date: May 29, 2025

(30) Foreign Application Priority Data
Dec. 21, 2022 (JP) 2022-203996

(51) Int. Cl. H10W 40/25; H10W 40/20; H10W 90/00

(52) U.S. Cl. CPC H10W 40/251; H10W 40/242; H10W 90/736

(57) ABSTRACT

Provided is an on-board electronic control device employing a room-temperature curable heat dissipation material having a curing time at 15 °C of 40 hours or less. The on-board electronic control device according to the present invention is characterized in that a predetermined heat dissipation material is interposed between an electronic component and a heat dissipation member, the predetermined heat dissipation material is a material having a silicone resin as a matrix, and, in a case where a molar concentration [—Si—CH═CH₂] of a vinyl group structure and a molar concentration [—Si—CH₂CH₂—Si—] of a main chain structure in the silicone resin are quantitatively analyzed using a nuclear magnetic resonance apparatus, a relationship “[—Si—CH═CH₂]/[—Si—CH₂CH₂—Si—]≤0.85” is satisfied.

### TECHNICAL FIELD

The present invention relates to an on-board electronic control device in which a heat dissipation material is interposed between an electronic component and a heat dissipation member.

### BACKGROUND ART

Technologies relating to advanced driving assistance systems (ADAS) and automatic driving (AD) in the driving of automobiles and the like have greatly progressed in recent years, and further development is expected in the future. In ADAS and AD, an electronic control unit (ECU) plays a very important role, and many ECUs are mounted according to the various applications/purposes. In the present specification, various ECUs mounted in an automobile or the like are collectively referred to as on-board ECUs.

An on-board ECU performs complicated and advanced calculations, and there is a large amount of heat generation from an electronic component such as an integrated circuit (IC) therein. Therefore, in order to prevent thermal runaway, heat dissipation by a heat dissipation member such as a heat sink or a heat spreader is necessary. At this time, in order to enhance heat dissipation efficiency, a heat dissipation material (may also be referred to as a TIM, a thermally conductive material, or a thermal interface material) is often interposed between the electronic component and the heat dissipation member.

For example, PTL 1 (JP 2018-198335 A) discloses a method for manufacturing an electronic control device that includes a housing formed by joining two constituent members, a circuit board on which an electronic component is mounted and which is housed in the housing, a waterproof seal material that seals a joint portion of each of the constituent members, and a thermally conductive material that thermally connects the electronic component and the housing, the method including:
a heating step of heating the housing in a state where a thermosetting material is used as the waterproof seal material, where a material having a property that the viscosity of the material increases when same is heated is used as the thermally conductive material, where the circuit board and the thermally conductive material are accommodated in the housing, and where the waterproof seal material before curing is disposed in the area where the constituent members are joined, the heating step curing the waterproof seal material and increasing the viscosity of the thermally conductive material.

According to PTL 1, it is possible to provide an electronic control device that enables improvements in coating workability by using a thermosetting heat-dissipating grease as a heat dissipation material, and that, by thermally curing the heat-dissipating grease, enables the suppression of deformation and outflow due to thermal deformation or vibration.

### CITATION LIST

### Patent Literature

PTL 1: JP 2018-198335 A

### SUMMARY OF INVENTION

### Technical Problem

Meanwhile, in recent years, there has been a strong demand for the reduction of greenhouse gas (for example, CO₂ gas) emissions from the viewpoint of global environmental protection, and efforts oriented toward achieving carbon neutrality are urgent issues for manufacturers of machines and devices. Because the technique of PTL 1 requires heat treatment, the discharge of CO₂ gas due to the heat treatment becomes an obstacle to achieving carbon neutrality. Note that, in the carbon neutralization, even in a case where the heat treatment itself is performed using electric power, it is necessary to consider the CO₂ gas generated when the electric power is generated.

As a part of efforts to achieve carbon neutrality, the present inventors have investigated replacing a conventional thermosetting TIM with a room-temperature curable TIM so that heat treatment does not need to be performed in the manufacture of an on-board ECU.

Here, because the room-temperature curable TIM is not subjected to heat treatment, the curing time is strongly affected by the working environment temperature. The working environment temperature varies depending on seasons and regions, but is assumed to decrease to about 15 °C as a minimum temperature.

The present inventors investigated the curing time of a room-temperature curable TIM at 15 °C. As a result, it was found that the curing time of the conventional two-liquid mixed room-temperature curable TIM at 15 °C takes about 72 hours, and that another problem, namely, an increase in work time/a decrease in throughput (a resulting cost increase) in on-board ECU manufacturing occurs.

Considering both the viewpoint of carbon neutralization and the viewpoint of work time/throughput, the allowable upper limit of the curing time at 15 °C is considered to be 40 hours. Therefore, an object of the present invention is to provide an on-board ECU that uses a room-temperature curable TIM having a curing time at 15 °C of 40 hours or less.

### Solution to Problem

One aspect of the present invention provides an on-board electronic control device in which a predetermined heat dissipation material is interposed between an electronic component and a heat dissipation member,
wherein the predetermined heat dissipation material is a material having a silicone resin as a matrix, and
wherein, in a case where a molar concentration [—Si—CH═CH₂] of a vinyl group structure and a molar concentration [—Si—CH₂CH₂—Si—] of a main chain structure in the silicone resin are quantitatively analyzed using a nuclear magnetic resonance apparatus (NMR), a relationship “[—Si—CH═CH₂]/[—Si—CH₂CH₂—Si—]≤0.85” is satisfied.

The present invention makes it possible to freely combine and add the following improvements and changes in the on-board electronic control device according to the present invention.
(i) In a case where the molar concentration of the vinyl group structure [—Si—CH═CH₂] and the molar concentration of a main skeleton structure [—O—Si—(CH₃)₂—] in the silicone resin are quantitatively analyzed using a nuclear magnetic resonance apparatus, a relationship “[—Si—CH═CH₂]/[—O—Si—(CH₃)₂—]≤0.95” is satisfied.
(ii) In the silicone resin, a molar concentration [—Si—CH═CH₂] of the vinyl group structure and a molar concentration [—Si—CH₂CH₂—Si—] of the main chain structure satisfy a relationship “[—Si—CH═CH₂]/[—Si—CH₂CH₂—Si—]≤0.60”.
(iii) In the silicone resin, a molar concentration [—Si—CH═CH₂] of the vinyl group structure and a molar concentration [—O—Si—(CH₃)₂—] of the main skeleton structure satisfy a relationship “[—Si—CH═CH₂]/[—O—Si—(CH₃)₂—]≤0.65”.
(iv) In the silicone resin, a molar concentration [—Si—CH═CH₂] of the vinyl group structure and a molar concentration [—Si—CH₂CH₂—Si—] of the main chain structure satisfy a relationship “[—Si—CH═CH₂]/[—Si—CH₂CH₂—Si—]≤0.40”.
(v) In the silicone resin, a molar concentration [—Si—CH═CH₂] of the vinyl group structure and a molar concentration [—O—Si—(CH₃)₂-] of the main skeleton structure satisfy a relationship “[—Si—CH═CH₂]/[—O—Si—(CH₃)₂—]≤0.45”.
(vi) The silicone resin has a storage elastic modulus exceeding 0.1 MPa.
(vii) The silicone resin has a storage elastic modulus of 0.15 MPa or more.
(viii) The silicone resin has a storage elastic modulus of 0.2 MPa or more.
(ix) The silicone resin has a tensile shear adhesive strength of 0.015 MPa or more.
(x) The silicone resin has a tensile shear adhesive strength of 0.020 MPa or more.
(xi) The silicone resin has a tensile shear adhesive strength of 0.025 MPa or more.
(xii) The silicone resin is a two-liquid mixed addition reaction-type room-temperature curable silicone resin.

### Advantageous Effects of Invention

According to the present invention, it is possible to provide an on-board ECU that contributes to carbon neutralization without greatly sacrificing productivity (for example, throughput) by using a room-temperature curable TIM having a curing time of no more than 40 hours even when the working environment temperature is 15 °C. Problems, configurations, and effects other than those described above will be clarified by the description of the embodiments provided below.

### BRIEF DESCRIPTION OF DRAWINGS

FIG. 1A is an exploded perspective schematic view illustrating an example of an on-board electronic control device (on-board ECU) according to the present invention.

FIG. 1B is an exploded perspective schematic view of the exploded perspective view illustrated in FIG. 1A as viewed from vertically opposite sides.

FIG. 1C is a partial cross-sectional schematic view of the on-board ECU illustrated in FIG. 1B.

FIG. 2 is an example of a graph showing the relationship, for a two-liquid mixed addition reaction-type silicone resin, between the storage elastic modulus and time.

FIG. 3 is a graph showing the relationship between the ratio “[—Si—CH═CH₂]/[—Si—CH₂CH₂—Si—]” of the molar concentration [—Si—CH═CH₂] of the vinyl group structure to the molar concentration [—Si—CH₂CH₂—Si—] of the main chain structure in the cured silicone resin, and “the curing time at 15 °C”.

### DESCRIPTION OF EMBODIMENTS

### [Basic Concepts of the Present Invention]

As described above, the present inventors investigated the curing time of a room-temperature curable TIM at 15 °C. As the room-temperature curable TIM, a two-liquid mixed addition reaction-type room-temperature curable silicone resin was selected, and the relationship between the chemical structure and the curing time was intensively investigated and studied with a focus on the chemical structure constituting the silicone resin.

As a result, the present inventors found that the curing time at 15 °C can be controlled to within 40 hours by controlling the molar concentration of the vinyl group structure [—Si—CH═CH₂], the molar concentration of the main chain structure [—Si—CH₂CH₂—Si—], and the molar concentration of the main skeleton structure [—O—Si—(CH₃)₂—] in the room-temperature curable silicone resin to have a predetermined relationship. The present invention was completed based on this finding.

Hereinafter, embodiments according to the present invention will be specifically described with reference to the drawings. However, the same reference signs are assigned to the same mechanisms and configurations (including cases where the difference is small), and thus redundant descriptions may be omitted. In addition, the present invention is not limited to or by the embodiments described herein, and can be appropriately combined with known techniques or improved on the basis of known techniques without departing from the technical concepts of the invention.

### First Embodiment

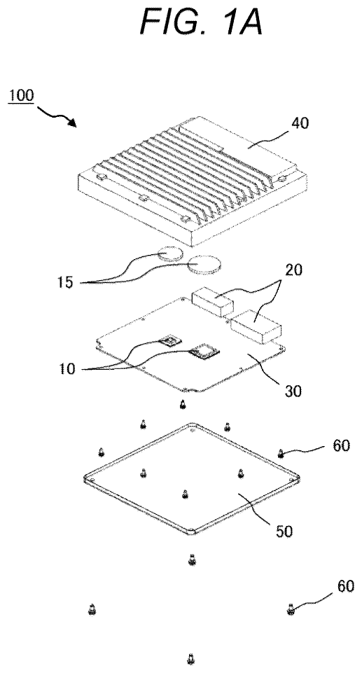

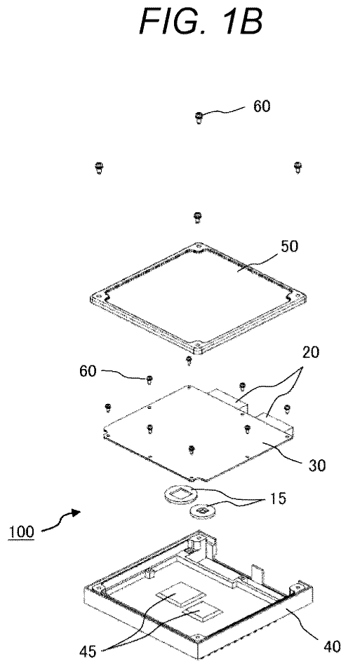

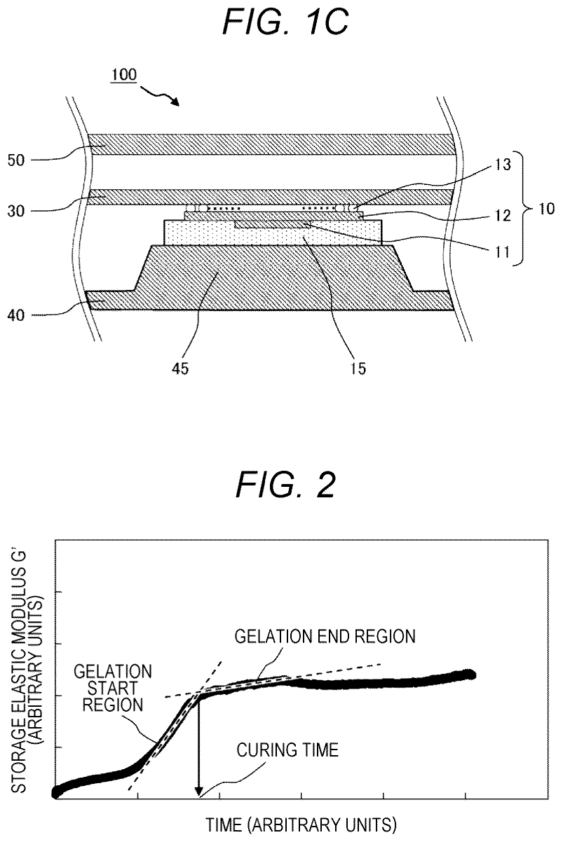

FIG. 1A is an exploded perspective schematic view illustrating an example of an on-board electronic control device (on-board ECU) according to the present invention, FIG. 1B is an exploded perspective schematic view of the exploded perspective view illustrated in FIG. 1A as viewed from vertically opposite sides, and FIG. 1C is a partial cross-sectional schematic view of the on-board ECU illustrated in FIG. 1B.

As described above, an on-board ECU is a type of computer that electronically controls various applications/purposes in the driving of an automobile or the like (for example, an engine, a transmission, steering, an airbag, and the like), and includes an electronic circuit therein. As illustrated in FIGS. 1A to 1C, an on-board ECU 100 is an example in which, among a cover 40, a base 50, and a fastener 60 that constitute the housing, the cover 40 also serves as a heat dissipation member. An electronic component 10 and a connector 20 are mounted (electrically connected) to a circuit board 30 to form an electronic circuit, and a heat dissipation material 15 is accommodated in the housing (the cover 40 and base 50) while being interposed between the electronic component 10 and the cover 40.

Each part will now be described more specifically.

The electronic component 10 is not particularly limited as long as same is for on-board use, for example, a semiconductor element such as a central processing unit (CPU), a graphics processing unit (GPU), a system-on-a-chip (SoC), or a double-data-rate synchronous dynamic random access memory (DDR SDRAM) is used. In FIG. 1C, the electronic component 10 is intended to depict a BGA (Boll Grid Array) package in which an IC chip 11 is connected atop an interposer 12 and connected to a circuit board 30 via a bump 13. As a matter of course, the package is not limited to a BGA package, and may be a lead frame-type package.

The connector 20 is a part that electrically connects the electronic component 10 mounted on the circuit board 30 to an external device. The connector 20 is not particularly limited, and a conventional on-board connector can be appropriately used.

The circuit board 30 is a board obtained by forming metal wiring on a base material of an electric insulator, and a conventional on-board circuit board can be appropriately used, similarly to the electronic component 10 and the connector 20. In the example illustrated in FIGS. 1A to 1B, a fixing hole is provided in the outer peripheral region, and fixing to the cover 40 is secured by means of a fastener 60 (for example, a fixing screw).

The cover 40 and the base 50 constitute a waterproof and dustproof sealed housing by being combined by means of the fastener 60. In the example illustrated in FIGS. 1A to 1C, the cover 40 also serves as a heat dissipation member, as described above. The heat dissipation material (TIM) 15 is disposed so as to be sandwiched between and abut against the cover 40 and the electronic component 10, thus enabling the heat of the electronic component 10 to be efficiently transferred to the cover 40. Details of the TIM 15 will be described below.

A heat dissipation seat 45 formed on the cover 40 is not an essential component in the present invention, but is preferably formed from the viewpoint of heat dissipation efficiency and assembly efficiency. FIGS. 1A to 1B illustrate an example in which two heat dissipation seats 45 are formed so as to correspond to two electronic components 10, respectively. However, one heat dissipation seat 45 may also correspond to two electronic components 10.

The material of the cover 40 and the base 50 are not particularly limited as long as heat resistance, waterproofness, dustproofness, and thermal conductivity corresponding to on-board use can be secured, and a metal material (for example, an aluminum alloy, a magnesium alloy, or a steel material) or a highly thermally conductive resin material (for example, a polybutylene terephthalate resin (PBT), a polyphenylene sulfide resin (PPS), or a polyamide resin (PA6) containing a thermally conductive filler may be used) can be appropriately used. The heat dissipation member is not limited to the cover 40, and the base 50 may also serve as the heat dissipation member, or both the cover 40 and the base 50 may also serve as heat dissipation members.

In addition to functioning as a thermally conductive material, the TIM 15 is also required to function as an adhesive/pressure sensitive adhesive. Before curing, it is preferable to have fluidity from the viewpoint of workability, and for example, the viscosity is preferably 100 Pa·s or more and 600 Pa·s or less. Meanwhile, after curing, it is preferable not to cause positional displacement or outflow due to vibration or stress during vehicle travel, and for example, it is preferable that the storage elastic modulus G′ exceeds 0.1 MPa and/or the tensile shear adhesive strength is 0.015 MPa or more. More specifically, a material having a silicone resin as a matrix is preferably used as the TIM 15, and a two-liquid mixed addition reaction-type room-temperature curable silicone resin in particular is preferable.

The silicone resin is a synthetic polymer material having a main skeleton formed by a siloxane bond (Si—O—Si bond). The silicone resin has excellent heat resistance (exceeding 200 °C) and chemical stability, and also has the property of an elastic body, and thus has the advantage of being able to absorb and mitigate vibration and impact.

In the two-liquid mixed addition reaction-type silicone resin, a vinyl group “—Si—CH═CH₂” as a main agent and a —Si—H group as a curing agent are cured by undergoing an addition reaction in a catalytic environment (usually a platinum catalyst). In the present invention, the time at which this addition reaction ends is defined as the curing time. This curing time can be determined from the temporal change of the storage elastic modulus G′ of the resin.

FIG. 2 is an example of a graph showing the relationship, for a two-liquid mixed addition reaction-type silicone resin, between the storage elastic modulus and time. When the main agent and the curing agent are mixed, as shown in FIG. 2, the two-liquid mixed addition reaction-type silicone resin exhibits a gelation start region (region where curing starts and proceeds) where the storage elastic modulus rapidly increases, and then reaches a gelation end region (region where curing ends) where the storage elastic modulus is almost saturated. It has been reported that a basic skeleton is formed in the gelation end region in the addition reaction of a silicone resin, and the curing time is defined as the time of intersection between the tangent of the gelation start region and the tangent of the gelation end region. The present invention also adopts this definition.

In the cured silicone resin, there are a main skeleton structure “—O—Si—(CH₃)₂—”, a main chain structure “—Si—CH₂CH₂—Si—”, and a vinyl group structure “—Si—CH═CH₂” as chemical structures. As a result of earnest investigations and studies on the relationship between these chemical structures and the curing time, the present inventors have found that the curing time at 15 °C can be controlled to within 40 hours by controlling the molar concentrations of these chemical structures to have a predetermined relationship. The molar concentration of each chemical structure can be measured by means of quantitative analysis using a nuclear magnetic resonance apparatus (NMR).

The ratio of the molar concentration of the vinyl group structure [—Si—CH═CH₂] to the molar concentration of the main chain structure [—Si—CH₂CH₂—Si—] in the cured silicone resin is preferably controlled to “[—Si—CH═CH₂]/[—Si—CH₂CH₂—Si—]≤0.85”, and thus the curing time at 15 °C can be set to 40 hours or less. It is more preferable to control “[—Si—CH═CH₂]/[—Si—CH₂CH₂—Si—]≤0.60”, and the curing time at 15 °C can be set to 30 hours or less. It is more preferable to control “[—Si—CH═CH₂]/[—Si—CH₂CH₂—Si—]≤0.40”, and the curing time at 15 °C can be set to 24 hours or less.

Similarly, the ratio of the molar concentration of the vinyl group structure [—Si—CH═CH₂] to the molar concentration of the main skeleton structure [—O—Si—(CH₃)₂—] in the cured silicone resin is preferably controlled to “[—Si—CH═CH₂]/[—O—Si—(CH₃)₂—]≤0.95”, whereby the curing time at 15 °C can be set to 40 hours or less. It is more preferable to control “[—Si—CH═CH₂]/[—O—Si—(CH₃)₂—]≤0.65”, and the curing time at 15 °C can be set to 30 hours or less. It is more preferable to control “[—Si—CH═CH₂]/[—O—Si—(CH₃)₂—]≤0.45”, and the curing time at 15 °C can be set to 24 hours or less.

The molar concentration [—Si—CH═CH₂] of the vinyl group structure in the cured silicone resin is preferably 0.3 mol % or less, more preferably 0.25 mol % or less, still more preferably 0.2 mol % or less.

The production method is not particularly limited as long as the molar concentration relationship of the chemical structure in the cured silicone resin can ultimately be achieved, but examples of methods for controlling the molar concentration of the vinyl group structure remaining after curing include, for example, a method for controlling the molar concentration of the main chain structure “—Si—CH₂CH₂—Si—” and the vinyl group “—Si—CH═CH₂” in the main agent before mixing, a method for controlling the mixing ratio of the curing agent, and a method for controlling the amount of the platinum catalyst and the degree of chemical activity. As an example, when mixing is performed so that the molar concentration of the main chain structure “—Si—CH₂CH₂—Si—” in the main agent before mixing is 99.09 mol %, the molar concentration of the vinyl group “—Si—CH═CH₂” is 0.58 mol %, and the molar concentration of the —Si—H group in the curing agent is 0.38 mol %, a silicone resin having a curing time at 15 °C of 24 hours can be obtained.

In order to enhance heat dissipation efficiency between the electronic component and the heat dissipation member, the TIM preferably has a thermal conductivity of 1.5 W/m·K or more, and more preferably has a thermal conductivity of 2 W/m·K or more. To ensure such thermal conductivity, the TIM is preferably obtained by dispersing and mixing a thermally conductive filler using a silicone resin as a matrix. The thermally conductive filler is not particularly limited as long as same is an electrically insulating material having good thermal conductivity (for example, 2 W/m·K or more), and aluminum oxide, zinc oxide, magnesium oxide, silicon oxide, aluminum nitride, and boron nitride, for example, can be suitably used.

In order to increase the adhesive force and holding force of the TIM, it is preferable that the storage elastic modulus G′ of the cured silicone resin is high. However, when the storage elastic modulus G′ is too high, the adhesiveness is reduced, or the absorbability and relaxation of vibration and stress are diminished. A storage elastic modulus G′ that is too low cannot ensure an adequate holding force. In the present invention, the storage elastic modulus G′ of the cured silicone resin preferably exceeds 0.1 MPa and is 20 MPa or less, is more preferably 0.15 MPa or more and 10 MPa or less, and still more preferably 0.2 MPa or more and 5 MPa or less.

In addition, from the viewpoint of preventing positional displacement, the adhesive strength of the TIM preferably has a tensile shear adhesive strength of 0.015 MPa or more after curing, more preferably has a tensile shear adhesive strength of 0.020 MPa or more, and still more preferably has a tensile shear adhesive strength of 0.025 MPa or more.

### EXAMPLES

Hereinafter, the present invention will be described more specifically by means of various experiments. However, the present invention is not limited to or by the configurations and structures described in these experiments.

### Experiment 1

### Preparation of Comparative Example 1 and Examples 1 to 4

A commercially available two-liquid mixed addition reaction-type room-temperature curable silicone resin (Comparative Example 1) was prepared. Meanwhile, by controlling the molar concentrations of the main chain structure “—Si—CH₂CH₂—Si—” and the vinyl group “—Si—CH═CH₂” in the main agent before mixing and controlling the mixing ratio of the curing agent, two-liquid mixed addition reaction-type room-temperature curable silicone resins (Examples 1 to 4) having different molar concentrations of the vinyl group structure remaining in the silicone resin after curing were prepared.

### Experiment 2

### (Measurement of Curing Time of Room-Temperature Curable Silicone Resin)

Using the two-liquid mixed addition reaction-type room-temperature curable silicone resin (Comparative Example 1 and Examples 1 to 4) prepared in Experiment 1, the curing time at 15 °C was measured. The temporal change of the storage elastic modulus was measured under predetermined measurement conditions (sample thickness: 3 mm, jig diameter: 25 mm, temperature: 15 °C, vibration frequency: 1 Hz, strain: 0.01%) using a rheometer (Anton Paar Japan Co., Ltd., model: MCR 502), and the curing time was determined based on the same definition as in FIG. 2. In addition, the storage elastic modulus G′ at the time of curing time was also determined. The results are shown in Table 1 described below.

### Experiment 3

### (Measurement of Molar Concentration of Chemical Structure in Cured Silicone Resin)

Quantitative analysis of the molar concentration of the main skeleton structure [—O—Si—(CH₃)₂—], the molar concentration of the main chain structure [—Si—CH₂CH₂—Si—], and the molar concentration of the vinyl group structure [—Si—CH═CH₂] remaining in the resin was performed for each silicone resin (Comparative Example 1 and Examples 1 to 4) after curing. The molar concentration of each chemical structure was measured under predetermined measurement conditions (measurement seed: 1H, magnetic field strength: 11.7T (500 MHz in 1H nucleus), observation frequency range: −2.5 ppm to 12.5 ppm (450 pulse), number of points of data: 16384 points, measurement mode: 13C decoupling, repetition time: 30 s, number of integrations: 256 times, measurement solvent: deuterated chloroform, measurement temperature: room temperature) using an NMR apparatus (JEOL Ltd., Model: ECA-500FT-NMR), and the molar concentration ratio of each chemical structure was calculated. The results are also shown in Table 1.

### Experiment 4

### (Measurement of Tensile Shear Adhesive Strength of Cured Silicone Resin)

Using the two-liquid mixed addition reaction-type room-temperature curable silicone resin (Comparative Example 1 and Examples 1 to 4) prepared in Experiment 1, the tensile shear adhesive strength was measured in accordance with JIS K6850. Using a precision universal testing machine (Shimadzu Corporation, model: AGS-H 500 N), the maximum load was measured under the condition of a tensile speed of 5 mm/min, and divided by the shear area to determine the tensile shear adhesive strength. The results are also shown in Table 1.

TABLE 1
Experiment results of Comparative Example 1 and Examples 1 to 4

| | Comparative | Example | Example | Example | Example |
|---|---|---|---|---|---|
| | Example 1 | 1 | 2 | 3 | 4 |
| Curing time (h) at 15 °C | 72 | 34 | 29 | 24 | 17 |
| Storage elastic modulus | 0.10 | 0.18 | 0.20 | 0.22 | 0.29 |
| (MPa) | | | | | |
| [—Si—CH═CH₂]/ | 1.10 | 0.68 | 0.56 | 0.40 | 0.22 |
| [—Si—CH₂CH₂—Si—] | | | | | |
| [—Si—CH═CH₂]/ | 1.24 | 0.77 | 0.63 | 0.45 | 0.25 |
| [—O—Si—(CH₃)₂—] | | | | | |
| [—Si—CH═CH₂] | 0.34 | 0.28 | 0.24 | 0.19 | 0.12 |
| (mol %) | | | | | |
| Tensile shear adhesive | 0.014 | 0.024 | 0.026 | 0.028 | 0.032 |
| strength (MPa) | | | | | |

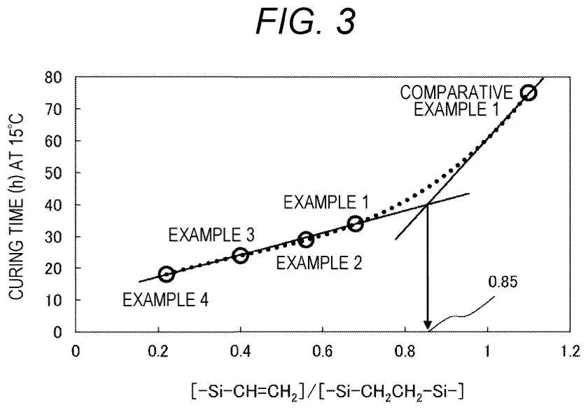

In order to investigate the relationship between the “curing time at 15 °C” and “[—Si—CH═CH₂]/[—Si—CH₂CH₂—Si—]”, the experimental results shown in Table 1 were plotted on a graph. FIG. 3 is a graph showing the relationship between the ratio “[—Si—CH═CH₂]/[—Si—CH₂CH₂—Si—]” of the molar concentration [—Si—CH═CH₂] of the vinyl group structure to the molar concentration [—Si—CH₂CH₂—Si—] of the main chain structure in the cured silicone resin, and “the curing time at 15 °C”.

As shown in FIG. 3, it is found that the “curing time at 15 °C“is reduced as” [—Si—CH═CH₂]/[—Si—CH₂CH₂—Si—]” decreases. In addition, the “curing time at 15 °C” in Comparative Example 1 is prominently large with respect to the slope of the plot in Examples 1 to 4. Therefore, an approximate curve was obtained for 5 plots, a tangent of the approximate curve was obtained for Comparative Example 1, and an approximate straight line/regression line was obtained for the plot of Examples 1 to 4.

As a result, it was found that the intersection points of the two straight lines were “[—Si—CH═CH₂]/[—Si—CH₂CH₂—Si—]=0.85” and “curing time at 15 °C: 40 h”. It is considered that the mode of the addition reaction related to the curing time is somewhat changed when “[—Si—CH═CH₂]/[—Si—CH₂CH₂—Si—]=0.85” is taken as a boundary. From this result, it became clear that the curing time at 15 °C can be curbed to within 40 hours by controlling “[—Si—CH═CH₂]/[—Si—CH₂CH₂—Si—]≤0.85”.

Note that, although not illustrated, it is confirmed separately that the same result as that in FIG. 3 can be obtained in the relationship between the “curing time at 15 °C” and the “[—Si—CH═CH₂]/[—O—Si—(CH₃)₂—]”.

Furthermore, from the results in Table 1, it is found that the tensile shear adhesive strength increases as the storage elastic modulus of the cured silicone resin increases. By controlling the storage elastic modulus of the cured silicone resin to exceed 0.1 MPa, the tensile shear adhesive strength can be set at 0.015 MPa or more.

The above-described embodiments and experiments have been described in order to facilitate understanding of the present invention, and the present invention is not limited to only the specific configurations described. For example, parts of the configuration of the embodiments can be replaced with configurations according to the technical common sense of those skilled in the art, and the configurations according to the technical common sense of those skilled in the art can also be added to the configurations of the embodiments. That is, in the present invention, parts of the configurations of the embodiments and experiments of the present specification can be deleted, replaced with other configurations, or added to other configurations without departing from the technical concept of the invention. For example, the heat dissipation material used in the present invention is not limited to an on-board ECU, and hence the present invention can also be applied to a heat dissipation material used for an inverter, a converter, or the like, other than an on-board inverter, converter, or the like.

### REFERENCE SIGNS LIST

100 on-board electronic control device
10 electronic component
11 chip
12 interposer
13 bump
15 heat dissipation material
20 connector
30 circuit board
40 cover
45 heat dissipation seat
50 base
60 fastener

1. An on-board electronic control device in which a predetermined heat dissipation material is interposed between an electronic component and a heat dissipation member,
wherein the predetermined heat dissipation material is a material having a silicone resin as a matrix, and
wherein, in a case where a molar concentration [—Si—CH═CH₂] of a vinyl group structure and a molar concentration [—Si—CH₂CH₂—Si—] of a main chain structure in the silicone resin are quantitatively analyzed using a nuclear magnetic resonance apparatus, a relationship “[—Si—CH═CH₂]/[—Si—CH₂CH₂—Si—]≤0.85” is satisfied.

2. The on-board electronic control device according to claim 1,
wherein, in a case where the molar concentration [—Si—CH═CH₂] of the vinyl group structure and a molar concentration [—O—Si—(CH₃)₂—] of a main skeleton structure in the silicone resin are quantitatively analyzed using the nuclear magnetic resonance apparatus, a relationship “[—Si—CH═CH₂]/[—O—Si—(CH₃)₂—]≤0.95” is satisfied.

3. The on-board electronic control device according to claim 1,
wherein, in the silicone resin, the molar concentration [—Si—CH═CH₂] of the vinyl group structure and the molar concentration [—Si—CH₂CH₂—Si—] of the main chain structure satisfy a relationship “[—Si—CH═CH₂]/[—Si—CH₂CH₂—Si—]≤0.60”.

4. The on-board electronic control device according to claim 2,
wherein, in the silicone resin, the molar concentration [—Si—CH═CH₂] of the vinyl group structure and the molar concentration [—O—Si—(CH₃)₂—] of the main skeleton structure satisfy a relationship “[—Si—CH═CH₂]/[—O—Si—(CH₃)₂—]≤0.65”.

5. The on-board electronic control device according to claim 3,
wherein, in the silicone resin, the molar concentration [—Si—CH═CH₂] of the vinyl group structure and the molar concentration [—Si—CH₂CH₂—Si—] of the main chain structure satisfy a relationship “[—Si—CH═CH₂]/[—Si—CH₂CH₂—Si—]≤0.40”.

6. The on-board electronic control device according to claim 4,
wherein, in the silicone resin, the molar concentration [—Si—CH═CH₂] of the vinyl group structure and the molar concentration [—O—Si—(CH₃)₂—] of the main skeleton structure satisfy a relationship “[—Si—CH═CH₂]/[—O—Si—(CH₃)₂—]≤0.45”.

7. The on-board electronic control device according to claim 1,
wherein the silicone resin has a storage elastic modulus exceeding 0.1 MPa.

8. The on-board electronic control device according to claim 1,
wherein the silicone resin has a storage elastic modulus of 0.15 MPa or more.

9. The on-board electronic control device according to claim 1,
wherein the silicone resin has a storage elastic modulus of 0.2 MPa or more.

10. The on-board electronic control device according to claim 1,
wherein the silicone resin has a tensile shear adhesive strength of 0.015 MPa or more.

11. The on-board electronic control device according to claim 1,
wherein the silicone resin has a tensile shear adhesive strength of 0.020 MPa or more.

12. The on-board electronic control device according to claim 1,
wherein the silicone resin has a tensile shear adhesive strength of 0.025 MPa or more.

13. The on-board electronic control device according to claim 1,
wherein the silicone resin is a two-liquid mixed addition reaction-type room-temperature curable silicone resin.

14. The on-board electronic control device according to claim 2,
wherein, in the silicone resin, the molar concentration [—Si—CH═CH₂] of the vinyl group structure and the molar concentration [—Si—CH₂CH₂—Si—] of the main chain structure satisfy a relationship “[—Si—CH═CH₂]/[—Si—CH₂CH₂—Si—]≤0.60”.

15. The on-board electronic control device according to claim 4,
wherein, in the silicone resin, the molar concentration [—Si—CH═CH₂] of the vinyl group structure and the molar concentration [—Si—CH₂CH₂—Si—] of the main chain structure satisfy a relationship “[—Si—CH═CH₂]/[—Si—CH₂CH₂—Si—]≤0.40”.

16. The on-board electronic control device according to claim 14, wherein, in the silicone resin, the molar concentration [—Si—CH═CH₂] of the vinyl group structure and the molar concentration [—Si—CH₂CH₂—Si—] of the main chain structure satisfy a relationship “[—Si—CH═CH₂]/[—Si—CH₂CH₂—Si—]≤0.40”.
